(19) United States
(12) Patent Application Publication
(10) Pub. No.: US 2015/0282358 A1
(43) Pub. Date: Oct. 1, 2015

(54) COMPOSITE CHASSIS WITH COSMETIC FINISH

(71) Applicants: MARK E. SPRENGER, Folsom, CA (US); PAUL J. GWIN, Orangevale, CA (US)

(72) Inventors: MARK E. SPRENGER, Folsom, CA (US); PAUL J. GWIN, Orangevale, CA (US)

(21) Appl. No.: 14/229,335

(22) Filed: Mar. 28, 2014

(51) Int. Cl. H05K 5/03; B29C 45/14

(52) U.S. Cl. CPC H05K 5/03; B29C 45/14631; B29K 2995/0016; B29K 2101/10

(57) ABSTRACT

Processes for forming a composite chassis having a cosmetic finish are described. A composite chassis having cosmetic finish may be formed from a preform formed from layers of a continuous fiber tape impregnated with thermoplastic resin and a reaction molding process where a cosmetic portion having a cosmetic finish is molded onto the preform. The preform may be cut to net shape prior to molding. Additionally, backmold features may be injection molded onto the preform during the molding process.

### BACKGROUND

Modern computing devices are continually getting smaller. This is particularly true for mobile devices, such as, for example, smart phones, tablet computer, laptops, ultrabooks, portable All-In-Ones (pAIO) or the like. Although these devices are smaller, the chassis still needs to be rigid enough to support the device. Various materials exist that are suitable for use as a chassis for modern computing devices. For example, some chassis for modern computing devices are made from aluminum. Aluminum chassis provide high strength and stiffness. However, they require significant processing (e.g., polishing, painting, or the like) after they are machined in order to provide a finished look. Furthermore, the finished product is prone to scratches and other noticeable signs of wear and tear. Additionally, aluminum chassis have a higher cost than, for example, plastic chassis. Plastic chassis, such as, for example, formed by injection molding, although having a lower cost than machined aluminum, typically do not have high strength or stiffness.

As another example, some modern computing devices have chassis made from composite materials. However, these composite chassis are often more expensive than aluminum to produce and have low yield. More specifically, it takes a significant amount of time to form each chassis. As such, manufacturing throughput can be limited. Furthermore, post-processing (e.g., painting, trimming, or the like) are necessary to provide a cosmetic finish on the chassis.

It is with respect to the above, that the present disclosure is provided.

### BRIEF DESCRIPTION OF THE DRAWINGS

FIG. 1 illustrates an embodiment of a computing device and manufacturing system for forming a composite chassis having a cosmetic finish.

FIGS. 2A-2D illustrate examples of a composite chassis having a cosmetic finish at various stages of manufacture.

FIGS. 3-4 illustrate examples of logic flows according to embodiments.

FIG. 5 illustrates a storage medium according to an embodiment.

FIG. 6 illustrates a processing architecture according to an embodiment.

### DETAILED DESCRIPTION

Various embodiments are generally directed to techniques to manufacture a composite chassis having a cosmetic finish for a computing device. In some examples, the composite chassis may be formed using a thermoforming process. The thermoforming process may include heating a preform formed from thermoplastic resin impregnated composite tape. The heated preform is then pressurized in a mold. Interconnect and standoff features may be formed by injection molding the features onto the preform. Additionally, a cosmetic surface may be applied by injection molding the cosmetic surface onto the preform while in the pressurized mold. Said differently, the cosmetic surface may be applied to the preform by a reaction molding process. As such, a composite chassis having a cosmetic finish and a method of forming the composite chassis having the cosmetic finish is described. In particular, the composite chassis has high rigidity and a cosmetic ready finish. Furthermore, the process of forming the chassis has high throughput and low cost. These and other example will be more fully described hereafter.

Reference is now made to the drawings, wherein like reference numerals are used to refer to like elements throughout. In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

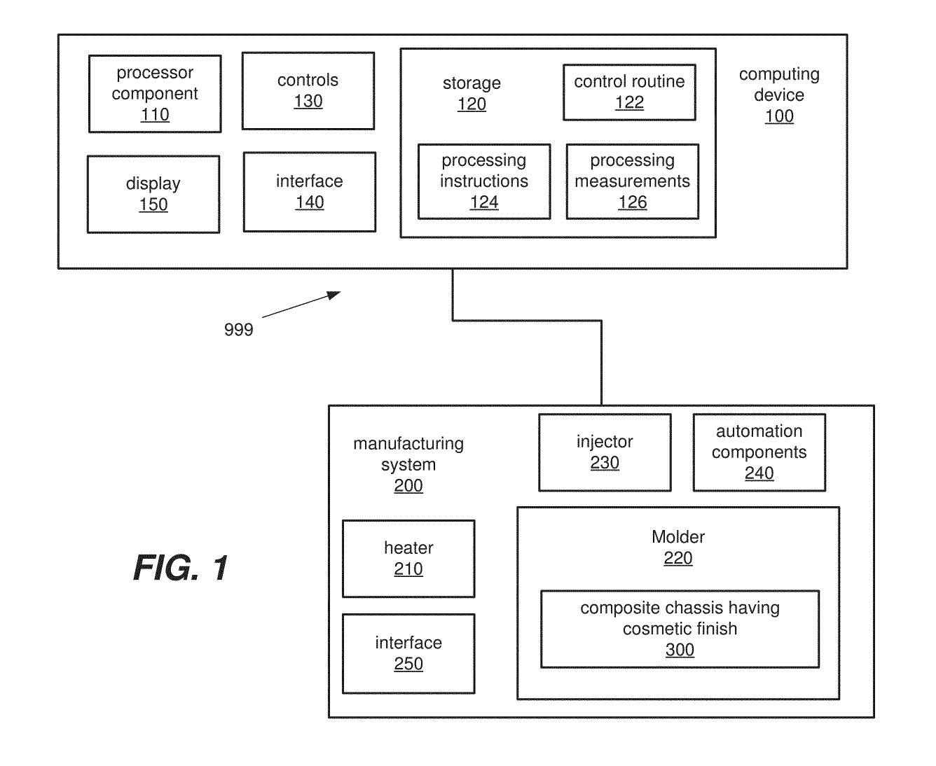

FIG. 1 is a block diagram of an embodiment incorporating a computing device 100 and a manufacturing system 200. In general, the computing device 100 is depicted configured to control the manufacturing system 200 to produce a composite chassis having a cosmetic finish 300. It is important to emphasize, however, that this is not intended to be limiting. For example, the composite chassis having a cosmetic finish 300 may be produced using a different configuration than depicted in FIG. 1. Additionally, although only the computing device 100 and the system 200 are depicted, other components may be necessary to form the composite chassis having a cosmetic finish as described herein.

Furthermore, it is important to note, that although the computing device 100 and the system 200 are depicted as separate, they may, in some embodiments, be incorporated into a single device. Furthermore, although not shown, other devices, components, and/or machinery may be used in forming the composite chassis having a cosmetic finish 300.

The computing device 100 may be any of a variety of types of computing devices, including without limitation, a desktop computer system, a data entry terminal, a laptop computer, a netbook computer, a tablet computer, a handheld personal computing device, a server, a cluster of servers, a server farm, a station, a wireless station, user equipment, and so forth. Embodiments are not limited in this context.

As depicted, the computing device 100 may exchange signals conveying processing instructions and processing measurements with the system 200 through network 999. Additionally, the computing device 100 may exchange other data entirely unrelated to the system 200 via the network 999. In various embodiments, the network 999 may be a single network possibly limited to extending within a single building or other relatively limited area, a combination of connected networks possibly extending a considerable distance, and/or may include the Internet. Thus, the network 999 may be based on any of a variety (or combination) of communications technologies by which signals may be exchanged, including without limitation, wired technologies employing electrically and/or optically conductive cabling, and wireless technologies employing infrared, radio frequency or other forms of wireless transmission. Furthermore, although the network 999 is shown as a wired network, it may in some examples be a wireless network.

In various embodiments, the computing device 100 incorporates one or more of a processor component 110, storage 120, controls 130, an interface 140, and a display 150. The storage 120 stores a control routine 122, processing instructions 124 and processing measurements 126.

The interface 140 may be configured to couple the computing device 100 to the network 999. During operation, the computing device 100 may receive and/or transmit the processing instructions 124 and the processing measurements 126. through the network 999 via the interface 140.

In the computing device 100, the control routine 122 incorporates a sequence of instructions operative on the processor component 110 in its role as a main processor component to implement logic to perform various functions. In executing the control routine 122, the processor component 110 transmits processing instructions 124 to the system 200 and receives processing measurements 126 from the system 200.

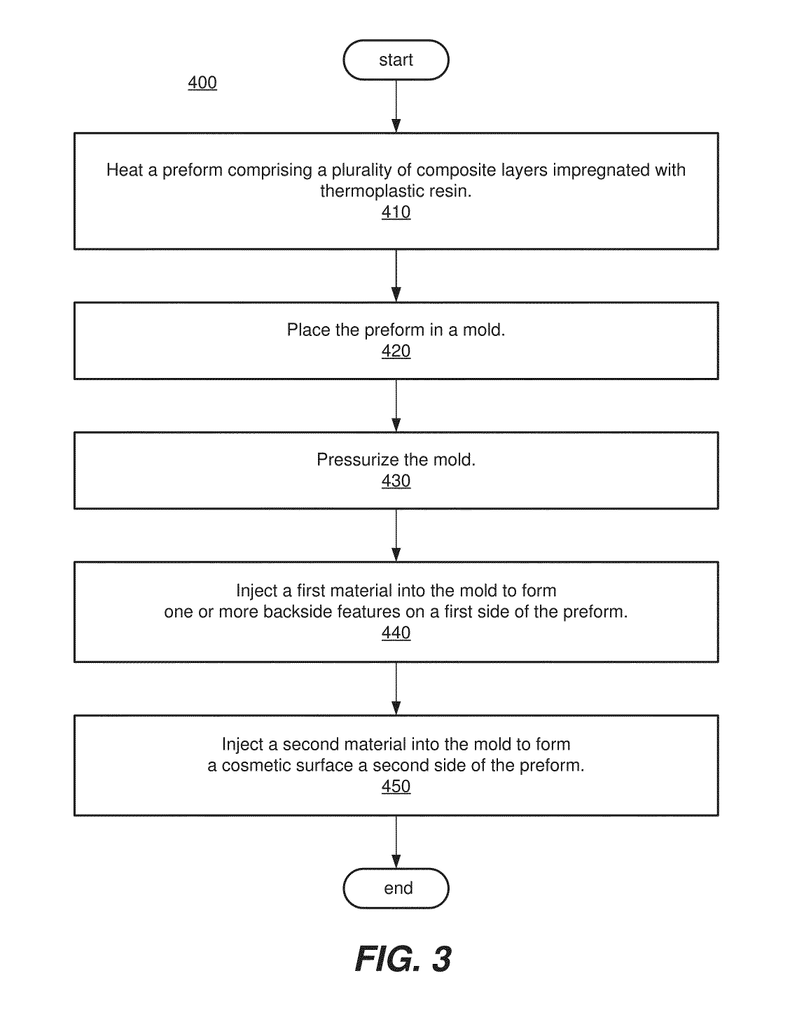

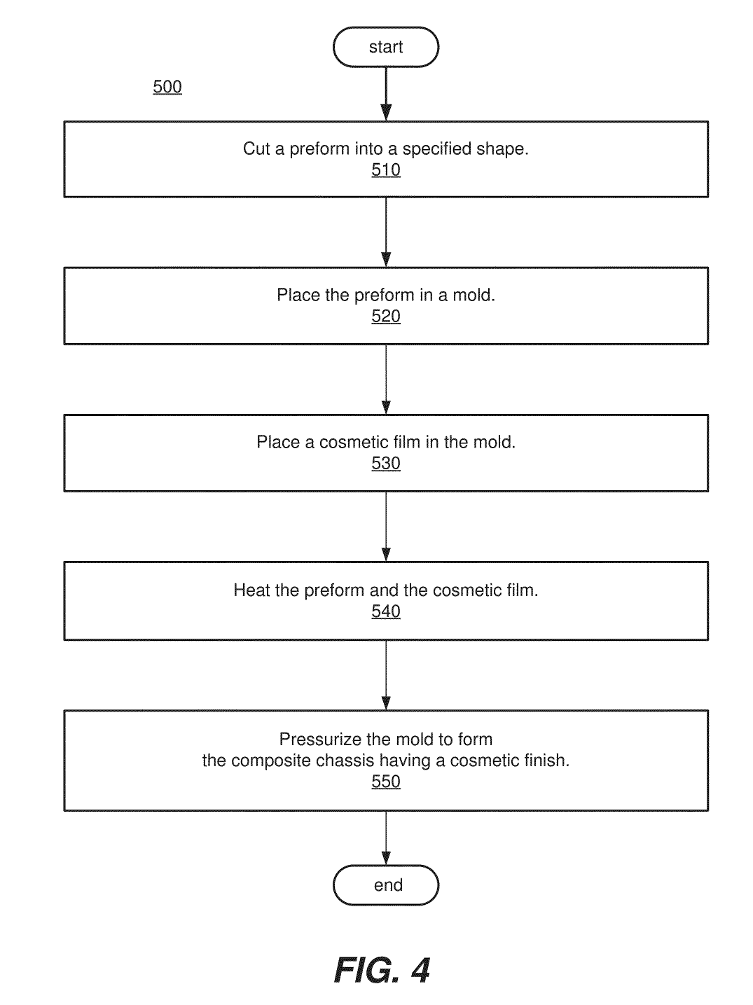

The processing instructions 124 may include indications of operations for the system 200 to perform (e.g., refer to FIGS. 3-4) in manufacturing the composite chassis having a cosmetic finish 300. Similarly, the processing measurements 126 may include indications of measurements, settings, or the like related to the manufacture of the composite chassis having a cosmetic finish 300.

In various embodiments, the system 200 incorporates one or more of a heater 210, a molder 220, an injector 230, automation components 240, and an interface 250. As noted above, the computing device 100 may be incorporated into the system 200. Alternatively, the system 200 may include a separate computing device (not shown) that includes a processor and memory and is configured to cause the system 200 to perform the operations described herein.

In some examples, the heater 210 may be an IR heater, an optical heater, a convection heater, a radiant heater. In some examples, the injector 230 may be injector for injection molding, or the like. In some examples, the automation components 240 may include robotic components, timing components, opening and closing components (e.g., for the mold, or the like), conveyor belts, loading and unloading components (e.g., for the mold, or the like), or other components useful in assisting automating the process of forming the composite chassis having a cosmetic finish as described herein.

The interface 250 may be configured to couple the system 200 to the network 999. During operation, the system 200 may receive and/or transmit one or more of the processing instructions 124 and the processing measurements 126 through the network 999 via the interface 250.

In various embodiments, the control routine 122 may include one or more of an operating system, device drivers and/or application-level routines (e.g., so-called “software suites” provided on disc media, “applets” obtained from a remote server, etc.). Where an operating system is included, the operating system may be any of a variety of available operating systems appropriate for whatever corresponding ones of the processor component 110. Where one or more device drivers are included, those device drivers may provide support for any of a variety of other components, whether hardware or software components, of the computer system 100 and/or the manufacturing system 200.

In various embodiments, the processor component 110 may include any of a wide variety of commercially available processors. Further, one or more of these processor components may include multiple processors, a multi-threaded processor, a multi-core processor (whether the multiple cores coexist on the same or separate dies), and/or a multi-processor architecture of some other variety by which multiple physically separate processors are in some way linked.

In various embodiments, the storage 120 may be based on any of a wide variety of information storage technologies, possibly including volatile technologies requiring the uninterrupted provision of electric power, and possibly including technologies entailing the use of machine-readable storage media that may or may not be removable. Thus, each of these storages may include any of a wide variety of types (or combination of types) of storage device, including without limitation, read-only memory (ROM), random-access memory (RAM), dynamic RAM (DRAM), Double-Data-Rate DRAM (DDR-DRAM), synchronous DRAM (SDRAM), static RAM (SRAM), programmable ROM (PROM), erasable programmable ROM (EPROM), electrically erasable programmable ROM (EEPROM), flash memory, polymer memory (e.g., ferroelectric polymer memory), ovonic memory, phase change or ferroelectric memory, silicon-oxide-nitride-oxide-silicon (SONOS) memory, magnetic or optical cards, one or more individual ferromagnetic disk drives, or a plurality of storage devices organized into one or more arrays (e.g., multiple ferromagnetic disk drives organized into a Redundant Array of Independent Disks array, or RAID array). It should be noted that although each of these storages is depicted as a single block, one or more of these may include multiple storage devices that may be based on differing storage technologies. Thus, for example, one or more of each of these depicted storages may represent a combination of an optical drive or flash memory card reader by which programs and/or data may be stored and conveyed on some form of machine-readable storage media, a ferromagnetic disk drive to store programs and/or data locally for a relatively extended period, and one or more volatile solid state memory devices enabling relatively quick access to programs and/or data (e.g., SRAM or DRAM). It should also be noted that each of these storages may be made up of multiple storage components based on identical storage technology, but which may be maintained separately as a result of specialization in use (e.g., some DRAM devices employed as a main storage while other DRAM devices employed as a distinct frame buffer of a graphics controller).

In various embodiments, the controls 130 may include any of a variety of controls (e.g., hardware, software, hardware and software, or the like) for providing input or receiving output from the computing device 100.

In various embodiments, the interface 140 may employ any of a wide variety of signaling technologies enabling computing devices to be coupled to other devices as has been described. Each of these interfaces may include circuitry providing at least some of the requisite functionality to enable such coupling. However, each of these interfaces may also be at least partially implemented with sequences of instructions executed by corresponding ones of the processor components (e.g., to implement a protocol stack or other features). Where electrically and/or optically conductive cabling is employed, these interfaces may employ signaling and/or protocols conforming to any of a variety of industry standards, including without limitation, RS-232C, RS-422, USB, Ethernet (IEEE-802.3) or IEEE-1394. Where the use of wireless signal transmission is entailed, these interfaces may employ signaling and/or protocols conforming to any of a variety of industry standards, including without limitation, IEEE 802.11a, 802.11b, 802.11g, 802.16, 802.20 (commonly referred to as “Mobile Broadband Wireless Access”); Bluetooth; ZigBee; or a cellular radiotelephone service such as GSM with General Packet Radio Service (GSM/GPRS), CDMA/1xRTT, Enhanced Data Rates for Global Evolution (EDGE), Evolution Data Only/Optimized (EV-DO), Evolution For Data and Voice (EV-DV), High Speed Downlink Packet Access (HSDPA), High Speed Uplink Packet Access (HSUPA), 4G LTE, etc.

In various embodiments, the display 150 may be based on any of a variety of displays (e.g., Plasma, LCD, LED, OLED, or the like) for displaying images.

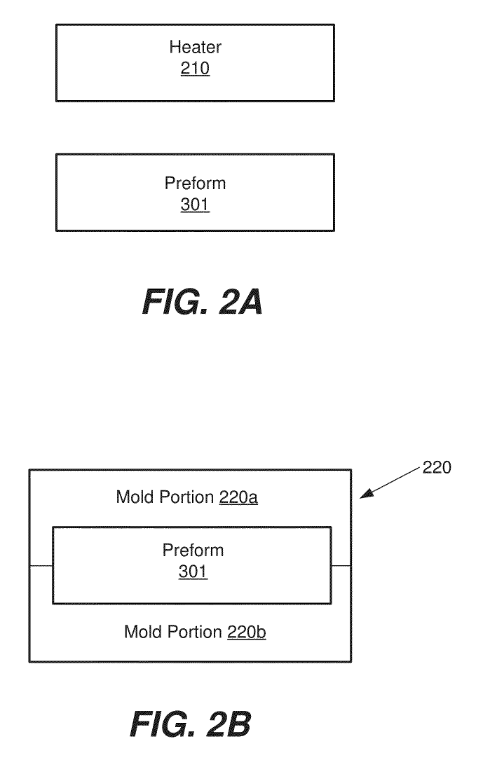

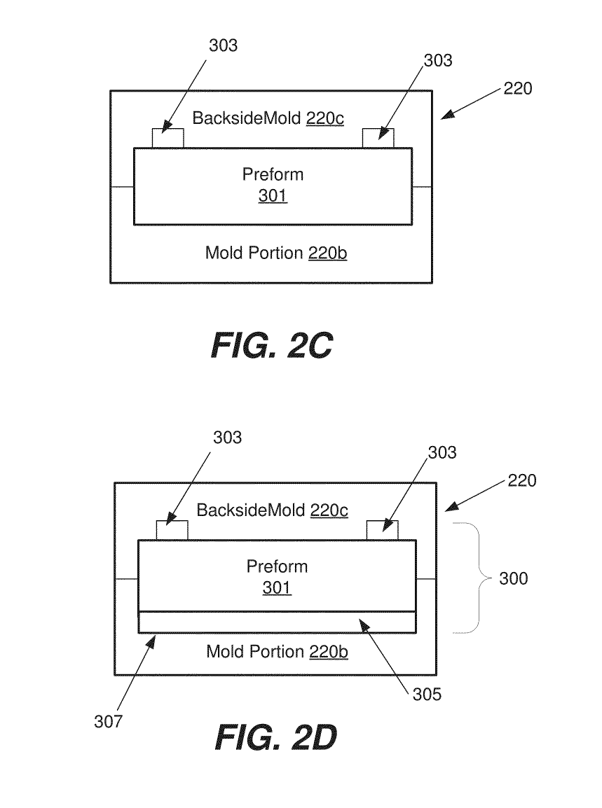

As noted, the processing instructions 124 may include indications of operations for the system 200 to perform. These operations are discussed in greater detail with reference to FIGS. 3-4. Additionally, exemplary stages of forming the composite chassis having a cosmetic finish 300 are shown in FIGS. 2A-2D. Said differently, these figures depict the composite chassis having a cosmetic finish 300 at various stages of manufacture.

In general, FIGS. 2A-2D each shows a stage of forming the composite chassis having a cosmetic finish 300. It is to be appreciated, however, that other stages, not depicted in FIGS. 2A-2D may be manifest when forming the composite chassis having a cosmetic finish 300. Furthermore, it is noted, that the composite chassis having a cosmetic finish depicted in FIGS. 1 and FIGS. 2A-2D is not drawn to scale nor is the shape of the composite chassis 300 meant to be limiting. Instead, the composite chassis 300 is merely depicted for purposes of clarity and completeness. The actual shape, dimensions, and aspects of the composite chassis 300 will depend upon the intended use and implementation.

Turning more specifically to FIG. 2A, the heater 210 may be used to heat a preform 301. The preform 301 may include one or more layers of a continuous fiber material. The continuous fiber material may be in the form of tapes, which may be laid up to form a composite blank (not shown). With some examples, the composite blank is a combination of thermoplastic matrix material and unidirectional fiber tapes such as carbon fiber tapes, glass tapes, aramid tapes, or the like. The continuous fiber material is combined with a thermoplastic resin to form the preform. Said differently, the composite blank may be formed by combining (e.g. co-mingling, heating and compressing, or the like) the thermoplastic matrix material with the continuous fiber material (e.g., unidirectional fiber tapes, unidirectional fiber fabrics, or the like). In some examples, the thermoplastic resin is a nylon based resin, polymer acrylonitrile butadiene styrene, or the like. With some examples, the thermoplastic resin is fire retardant. Additionally, the thermoplastic resin impregnated composite blank may be trimmed and or cut or calendared to a desired shape prior to entering the mold.

Turning more specifically to FIG. 2B, the preform 301 is depicted placed in the mold 220. The mold 220 may be pressurized to set the preform to the desired shape. With some examples, the automation components 240 may place the preform in the mold 220. As depicted, the mold includes a first portion 220a and a second portion 220b. However, alternative configurations and portion may be implemented. Examples are not limited in this context.

Turning more specifically to FIG. 2C, a first material is injection molded to a first side of the preform 301 to form backside features 303. In particular, the injector 230 may be used to inject the first material into the mold and/or onto the first surface of the preform 301. Alternatively, the automation components 240 may rotate the preform out of the mold (e.g., remove the mold portion 220a) and place a backside mold 220c over the first side of the preform 301. The backside features 303 may be formed using the backside mold 220c. In particular, the backside mold may include cavities corresponding to the desired backside features 303. The injector 230 may form the backside features by injection molding the first material onto the first side of the preform to form the backside features in the cavities.

Turning more specifically to FIG. 2D, a second material is molded to a second side of the preform 301 to form a cosmetic portion 305 having a cosmetic surface 307. In some examples, the mold 220 may be opened slightly and the injector may inject the second material into the mold. As another example, the second material may be a composite film inserted into the mold 220. The mold 220 may then be pressurized to form the composite chassis having a cosmetic surface 300 from the preform 301, the cosmetic portion 305, and/or the backside features 303.

It is important to note, that the cosmetic surface 307 has a significantly higher scratch resistant finish (e.g., 5H-6H) versus conventional cosmetic finishes, which may only be as high as 3H. It is important to note, however, that the hardness level of the finished surface may depend upon the implementation.

FIGS. 3-4 are block diagrams of logic flows of manufacturing a composite chassis having a cosmetic finish. In general, FIGS. 3-4 illustrate aspects of the forming the composite chassis having a cosmetic finish 300 of FIG. 1. In describing FIGS. 2-3, reference is made to FIG. 1 and FIG. 2A-2D. However, embodiments are not limited in this respect. Furthermore, the illustrated logic flows may be representative of some or all of the operations executed by one or more embodiments described herein. More specifically, the logic flows may illustrate operations performed by the processor component 110 in executing at least the control routines 122 and/or operations performed by components of the manufacturing system 200. For example, performance of a specific operation may include the processor component 110 executing the control routine 122 and transmitting processing instructions 124 to the manufacturing system 200, whereupon the manufacturing system 200 performs the specific operation. It is to be appreciated, that execution of the control routine 122 by the processing component 110 and transmission of processing instructions 124 may be performed at each operation, even where not mentioned for clarity. Embodiments are not limited in this context.

Turning more specifically to FIG. 3, the logic flow 400 may begin at block 410. At block 410, heat a preform comprising a plurality of composite layers impregnated with thermoplastic resin; the heater 210 may heat the preform 301. Continuing to block 420, place the preform in a mold; the automation components 240 may place the preform 301 in the mold 220. Continuing to block 430, pressurize the mold; the mold 220 may be pressurized, for example, using a compressor (not shown).

Continuing to block 440, inject a first material into the mold to form one or more backside features on a first side of the preform; the injectors 230 may inject a first material into the mold 220 to form the backside features 303 on the first side of the preform 301. In some examples, injecting the first material into the mold may include opening the mold to expose the first side of the preform 301. Subsequently, a backside feature mold (e.g., the backside mold 220c, or the like) may be placed over the first side of the preform 301. As described above, the backside feature mold 220c may include one or more cavities corresponding to the one or more backside features 303. The injectors 230 may fill the cavities with the first material to form the backside features 303. In some examples, the first material may be a plastic material.

In some examples, the injector may inject high pressure plastic through the preform 301 to form the backmold features 303 on the first side of the preform 301 without distorting the preform.

Continuing to block 450, inject a second material into the mold to form a cosmetic surface on a second side of the preform; the injectors 230 may inject a second material into the mold 220 to form the cosmetic portion 305 having the cosmetic surface 307. In some examples, injecting the second material into the mold to from the cosmetic surface may include opening the mold 220 to form a cavity between the second side of the preform 301 and an internal side of the mold 220 and filling the cavity with the second material.

With some examples, the second material is a thermal set material. In further examples, the second material is polycarbonate acrylonitrile butadiene styrene, thermoplastic-polyurethane, or the like. The mold 220 may be heated and/or pressurized once the second material is injected to form the cosmetic portion 305. In some examples, block 450 corresponds to a reaction molding operation. Said differently, the injectors 230 inject a reaction molding material (e.g., reaction molding polyurethane, or the like) into the mold. Whereupon the reaction is allowed to occur (e.g., the second material cures) and forms the composite portion 305 of the composite chassis having a cosmetic finish 300.

Turning more specifically to FIG. 4, the logic flow 500 may begin at block 510. At block 510, cut a preform into a specified shape; the preform 301 may be cut into a specified shape. In some examples, preform 301 may be cut on a CNC machine, an automated cutting or trimming machine, or the like. It is important to note, that with some examples, the composite chassis 300 leaves the mold 220 “net shape.” More specifically, there is not a requirement for post trimming and or cutting operations as the preform is cut to shape prior to entering the mold. Conversely, some prior processes require that a crimp edge be left around the chassis during processing. Such crimp edges must then be trimmed post-processing, which takes extra time to process and reduces yield.

Continuing to block 520, place the preform in the mold; the preform 301 may be placed in the mold 220. In some examples, automation components 240 may place the preform in the mold. Continuing to block 530, place a cosmetic film in the mold; the automation components 240 may place a cosmetic film (e.g., the cosmetic portion 305) into the mold 220.

Continuing to block 540, heat the preform and the mold; the heater 210 may heat the preform 301 and the cosmetic film. In some examples, heaters embedded in the mold heat the preform and cosmetic film.

Continuing to block 550, pressurize the mold to form the composite chassis having a cosmetic finish; the mold 220 is pressurized to form the composite chassis having a cosmetic finish 300. It is important to note, that the heating and pressurizing process described here may provide for an up to 10× reduction in the compression pressure needed mold a composite chassis.

Accordingly, a composite chassis having a cosmetic finish and the making thereof are disclosed. In particular, the cosmetic finish is formed on mold. More specifically, the cosmetic finish is formed while the composite chassis is formed. As such, there is no need for post processing (e.g., painting, or the like) of the chassis. Furthermore, the chassis has sufficient rigidity for modern electronic chassis. Additionally, the process has high throughput, and takes significantly (e.g., up to 50%) less time to complete than previous composite chassis forming processes and/or aluminum chassis machining process. Additionally, a significant savings in cost (e.g., up to 60%) versus conventional chassis (e.g., conventional thermoset composite, machined aluminum, or the like).

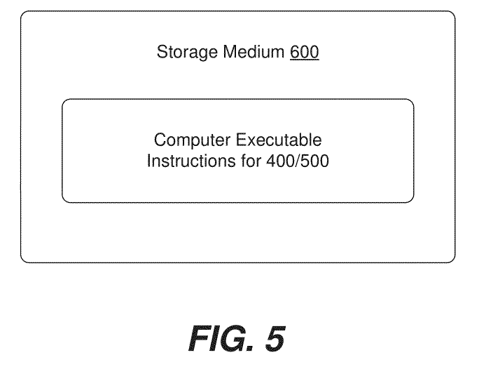

As described above, with some embodiments, the operations described herein include the processor component 110 executing at least the control routine 122. The control routine 122 may be computer executable instructions stored on a storage medium (e.g., 120). FIG. 5 illustrates an embodiment of a storage medium 600. The storage medium 600 may comprise an article of manufacture. In some examples, the storage medium 600 may include any non-transitory computer readable medium or machine readable medium, such as an optical, magnetic or semiconductor storage. The storage medium 600 may store various types of computer executable instructions, such as instructions to implement logic flows 400 and/or 500. Examples of a computer readable or machine readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The examples are not limited in this context.

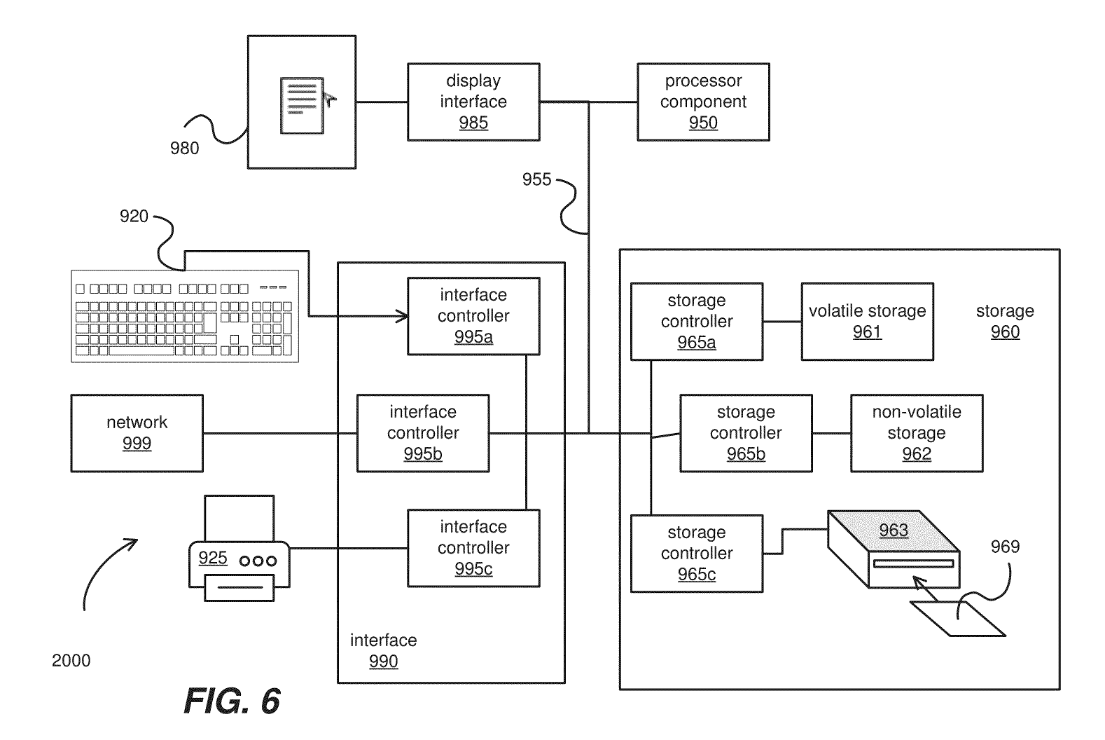

FIG. 6 illustrates an embodiment of an exemplary processing architecture 2000 suitable for implementing various embodiments as previously described. More specifically, the processing architecture 2000 (or variants thereof) may be implemented as part of the computing device 100.

The processing architecture 2000 may include various elements commonly employed in digital processing, including without limitation, one or more processors, multi-core processors, co-processors, memory units, chipsets, controllers, peripherals, interfaces, oscillators, timing devices, video cards, audio cards, multimedia input/output (I/O) components, power supplies, etc. As used in this application, the terms “system” and “component” are intended to refer to an entity of a computing device in which digital processing is carried out, that entity being hardware, a combination of hardware and software, software, or software in execution, examples of which are provided by this depicted exemplary processing architecture. For example, a component can be, but is not limited to being, a process running on a processor component, the processor component itself, a storage device (e.g., a hard disk drive, multiple storage drives in an array, etc.) that may employ an optical and/or magnetic storage medium, an software object, an executable sequence of instructions, a thread of execution, a program, and/or an entire computing device (e.g., an entire computer). By way of illustration, both an application running on a server and the server can be a component. One or more components can reside within a process and/or thread of execution, and a component can be localized on one computing device and/or distributed between two or more computing devices. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to one or more signal lines. A message (including a command, status, address or data message) may be one of such signals or may be a plurality of such signals, and may be transmitted either serially or substantially in parallel through any of a variety of connections and/or interfaces.

As depicted, in implementing the processing architecture 2000, a computing device may include at least a processor component 950, a storage 960, an interface 990 to other devices, and a coupling 955. As will be explained, depending on various aspects of a computing device implementing the processing architecture 2000, including its intended use and/or conditions of use, such a computing device may further include additional components, such as without limitation, a display interface 985.

The coupling 955 may include one or more buses, point-to-point interconnects, transceivers, buffers, crosspoint switches, and/or other conductors and/or logic that communicatively couples at least the processor component 950 to the storage 960. Coupling 955 may further couple the processor component 950 to one or more of the interface 990, the audio subsystem 970 and the display interface 985 (depending on which of these and/or other components are also present). With the processor component 950 being so coupled by couplings 955, the processor component 950 is able to perform the various ones of the tasks described at length, above, for whichever one(s) of the aforedescribed computing devices implement the processing architecture 2000. Coupling 955 may be implemented with any of a variety of technologies or combinations of technologies by which signals are optically and/or electrically conveyed. Further, at least portions of couplings 955 may employ timings and/or protocols conforming to any of a wide variety of industry standards, including without limitation, Accelerated Graphics Port (AGP), CardBus, Extended Industry Standard Architecture (E-ISA), Micro Channel Architecture (MCA), NuBus, Peripheral Component Interconnect (Extended) (PCI-X), PCI Express (PCI-E), Personal Computer Memory Card International Association (PCMCIA) bus, HyperTransport™, QuickPath, and the like.

As previously discussed, the processor component 950 (corresponding to the processor component 110) may include any of a wide variety of commercially available processors, employing any of a wide variety of technologies and implemented with one or more cores physically combined in any of a number of ways.

As previously discussed, the storage 960 (corresponding to the storage 120) may be made up of one or more distinct storage devices based on any of a wide variety of technologies or combinations of technologies. More specifically, as depicted, the storage 960 may include one or more of a volatile storage 961 (e.g., solid state storage based on one or more forms of RAM technology), a non-volatile storage 962 (e.g., solid state, ferromagnetic or other storage not requiring a constant provision of electric power to preserve their contents), and a removable media storage 963 (e.g., removable disc or solid state memory card storage by which information may be conveyed between computing devices). This depiction of the storage 960 as possibly including multiple distinct types of storage is in recognition of the commonplace use of more than one type of storage device in computing devices in which one type provides relatively rapid reading and writing capabilities enabling more rapid manipulation of data by the processor component 950 (but possibly using a “volatile” technology constantly requiring electric power) while another type provides relatively high density of non-volatile storage (but likely provides relatively slow reading and writing capabilities).

Given the often different characteristics of different storage devices employing different technologies, it is also commonplace for such different storage devices to be coupled to other portions of a computing device through different storage controllers coupled to their differing storage devices through different interfaces. By way of example, where the volatile storage 961 is present and is based on RAM technology, the volatile storage 961 may be communicatively coupled to coupling 955 through a storage controller 965a providing an appropriate interface to the volatile storage 961 that perhaps employs row and column addressing, and where the storage controller 965a may perform row refreshing and/or other maintenance tasks to aid in preserving information stored within the volatile storage 961. By way of another example, where the non-volatile storage 962 is present and includes one or more ferromagnetic and/or solid-state disk drives, the non-volatile storage 962 may be communicatively coupled to coupling 955 through a storage controller 965b providing an appropriate interface to the non-volatile storage 962 that perhaps employs addressing of blocks of information and/or of cylinders and sectors. By way of still another example, where the removable media storage 963 is present and includes one or more optical and/or solid-state disk drives employing one or more pieces of machine-readable storage medium 969, the removable media storage 963 may be communicatively coupled to coupling 955 through a storage controller 965c providing an appropriate interface to the removable media storage 963 that perhaps employs addressing of blocks of information, and where the storage controller 965c may coordinate read, erase and write operations in a manner specific to extending the lifespan of the machine-readable storage medium 969.

One or the other of the volatile storage 961 or the non-volatile storage 962 may include an article of manufacture in the form of a machine-readable storage media on which a routine including a sequence of instructions executable by the processor component 950 to implement various embodiments may be stored, depending on the technologies on which each is based. By way of example, where the non-volatile storage 962 includes ferromagnetic-based disk drives (e.g., so-called “hard drives”), each such disk drive typically employs one or more rotating platters on which a coating of magnetically responsive particles is deposited and magnetically oriented in various patterns to store information, such as a sequence of instructions, in a manner akin to storage medium such as a floppy diskette. By way of another example, the non-volatile storage 962 may be made up of banks of solid-state storage devices to store information, such as sequences of instructions, in a manner akin to a compact flash card. Again, it is commonplace to employ differing types of storage devices in a computing device at different times to store executable routines and/or data. Thus, a routine including a sequence of instructions to be executed by the processor component 950 to implement various embodiments may initially be stored on the machine-readable storage medium 969, and the removable media storage 963 may be subsequently employed in copying that routine to the non-volatile storage 962 for longer term storage not requiring the continuing presence of the machine-readable storage medium 969 and/or the volatile storage 961 to enable more rapid access by the processor component 950 as that routine is executed.

As previously discussed, the interface 990 (corresponding to the interface 140) may employ any of a variety of signaling technologies corresponding to any of a variety of communications technologies that may be employed to communicatively couple a computing device to one or more other devices. Again, one or both of various forms of wired or wireless signaling may be employed to enable the processor component 950 to interact with input/output devices (e.g., the depicted example keyboard 920 or printer 925) and/or other computing devices, possibly through a network or an interconnected set of networks. In recognition of the often greatly different character of multiple types of signaling and/or protocols that must often be supported by any one computing device, the interface 990 is depicted as including multiple different interface controllers 995a, 995b and 995c. The interface controller 995a may employ any of a variety of types of wired digital serial interface or radio frequency wireless interface to receive serially transmitted messages from user input devices, such as the depicted keyboard 920. The interface controller 995b may employ any of a variety of cabling-based or wireless signaling, timings and/or protocols to access other computing devices through the depicted network 999 (perhaps a network made up of one or more links, smaller networks, or perhaps the Internet). The interface 995c may employ any of a variety of electrically conductive cabling enabling the use of either serial or parallel signal transmission to convey data to the depicted printer 925. Other examples of devices that may be communicatively coupled through one or more interface controllers of the interface 990 include, without limitation, microphones, remote controls, stylus pens, card readers, finger print readers, virtual reality interaction gloves, graphical input tablets, joysticks, other keyboards, retina scanners, the touch input component of touch screens, trackballs, various sensors, a camera or camera array to monitor movement of persons to accept commands and/or data signaled by those persons via gestures and/or facial expressions, sounds, laser printers, inkjet printers, mechanical robots, milling machines, etc.

Where a computing device is communicatively coupled to (or perhaps, actually incorporates) a display (e.g., the depicted example display 980, corresponding to the display 150), such a computing device implementing the processing architecture 2000 may also include the display interface 985. Although more generalized types of interface may be employed in communicatively coupling to a display, the somewhat specialized additional processing often required in visually displaying various forms of content on a display, as well as the somewhat specialized nature of the cabling-based interfaces used, often makes the provision of a distinct display interface desirable. Wired and/or wireless signaling technologies that may be employed by the display interface 985 in a communicative coupling of the display 980 may make use of signaling and/or protocols that conform to any of a variety of industry standards, including without limitation, any of a variety of analog video interfaces, Digital Video Interface (DVI), DisplayPort, etc.

More generally, the various elements of the computing devices described and depicted herein may include various hardware elements, software elements, or a combination of both. Examples of hardware elements may include devices, logic devices, components, processors, microprocessors, circuits, processor components, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Further, some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other. Furthermore, aspects or elements from different embodiments may be combined.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims. The detailed disclosure now turns to providing examples that pertain to further embodiments. The examples provided below are not intended to be limiting.

### EXAMPLE 1

A method of manufacturing a composite chassis having a cosmetic surface. The method may include heating a preform, the preform comprising a plurality of composite layers impregnated with thermoplastic resin, placing the preform in a mold, pressurizing the mold, injecting a first material into the mold to form one or more backside features on a first side of the preform, and injecting a second material into the mold to form a cosmetic surface on a second side of the preform.

### EXAMPLE 2

The method of example 1, wherein the first side is different than the second side.

### EXAMPLE 3

The method of example 1, wherein the first material is different than the second material.

### EXAMPLE 4

The method of example 1, injecting the second material into the mold comprises opening the mold to form a cavity between the second side of the preform and an internal side of the mold, and filling the cavity with the second material.

### EXAMPLE 5

The method of example 4, wherein the second material is a thermal set material, injecting the second material into the mold further comprises heating second material.

### EXAMPLE 6

The method of example 5, wherein the second material is selected from the group consisting of polycarbonate acrylonitrile butadiene styrene and thermoplastic-polyurethane.

### EXAMPLE 7

The method of example 1, injecting the first material into the mold comprises opening the mold to expose the first side of the preform, placing a backside feature mold over the first side of the preform, the backside feature mold including one or more cavities corresponding to the one or more backside features, and filling the one or more cavities with the first material.

### EXAMPLE 8

The method of example 1, further comprising laying a plurality of continuous fiber material tapes to form a composite blank, and impregnating the composite blank with a thermoplastic resin to form the preform.

### EXAMPLE 9

The method of example 8, further comprising cutting the preform to a specified shape.

### EXAMPLE 10

The method of example 8, wherein the plurality of continuous fiber material tapes are selected from the group consisting of carbon fiber tapes, glass tapes, and aramid tapes.

### EXAMPLE 11

The method of example 8, wherein the thermoplastic resin is selected from the group consisting of nylon and polymer acrylonitrile butadiene styrene.

### EXAMPLE 12

The method of example 8, wherein the thermoplastic resin is fire retardant.

### EXAMPLE 13

The method of example 1, further comprising removing the preform including the backside features and the cosmetic surface, wherein the preform is net shape.

### EXAMPLE 14

A method of manufacturing a composite chassis having a cosmetic surface. The method may include cutting a preform comprising a plurality of composite layers impregnated with thermoplastic resin into a specified shape, placing the preform in a mold, placing a cosmetic film into the mold, heating the preform and cosmetic film, and pressurizing the mold to form the composite chassis having a cosmetic finish.

### EXAMPLE 15

The method of example 14, further comprising trimming the composite chassis having a cosmetic finish.

### EXAMPLE 16

The method of example 15, trimming the composite chassis having a cosmetic finish includes trimming the composite chassis using a CNC machine.

### EXAMPLE 17

The method of example 14, wherein heating the preform and cosmetic film and pressurizing the mold is done concurrently.

### EXAMPLE 18

The method of example 14, wherein heating the preform and cosmetic film and pressurizing the mold is done for less than 120 seconds.

### EXAMPLE 19

The method of example 14, wherein the cosmetic film is a thermal set material.

### EXAMPLE 20

The method of example 14, wherein the cosmetic film includes polycarbonate acrylonitrile butadiene styrene or thermoplastic-polyurethane.

### EXAMPLE 21

The method of example 14, further comprising injecting a first material into the mold to form one or more backside features on a first side of the preform.

### EXAMPLE 22

The method of example 14, further comprising injecting a first material into the mold to form backside features on a first side of the composite chassis.

### EXAMPLE 23

The method of example 22, injecting the first material into the mold comprises opening the mold to expose the first side of the preform, placing a backside feature mold over the first side of the preform, the backside feature mold including one or more cavities corresponding to the one or more backside features, and filling the one or more cavities with the first material.

### EXAMPLE 24

The method of example 14, further comprising laying a plurality of continuous fiber material tapes to form a composite blank, and impregnating the composite blank with a thermoplastic resin to form the preform.

### EXAMPLE 25

The method of example 24, wherein the plurality of continuous fiber material tapes are selected from the group consisting of carbon fiber tapes, glass tapes, and aramid tapes.

### EXAMPLE 26

The method of example 24, wherein the thermoplastic resin is selected from the group consisting of nylon and polymer acrylonitrile butadiene styrene.

### EXAMPLE 27

The method of example 24, wherein the thermoplastic resin is fire retardant.

### EXAMPLE 28

The method of example 14, further comprising removing the composite chassis from the mold, wherein the composite chassis is netshape.

### EXAMPLE 29

A composite chassis having a cosmetic finish. The composite chassis may include a first portion formed from a preform comprising a plurality of composite layers impregnated with thermoplastic resin, a backside feature portion molded to the preform to form one or more backside features on a first side of the preform, and a cosmetic portion molded to the preform to form a cosmetic surface on a second side of the preform.

### EXAMPLE 30

The composite chassis of example 29, wherein the cosmetic portion is less than or equal to 10% of the overall volume of the composite chassis.

### EXAMPLE 31

The composite chassis of example 29, wherein the first portion is less than or equal to 90% of the overall volume of the composite chassis.

### EXAMPLE 32

The composite chassis of example 29, wherein the cosmetic portion is selected from the group consisting of polycarbonate acrylonitrile butadiene styrene and thermoplastic-polyurethane.

### EXAMPLE 33

The cosmetic chassis of example 29, wherein the preform is a plurality of continuous fiber material tapes impregnated with a thermoplastic resin.

### EXAMPLE 34

The cosmetic chassis of example 33, wherein the plurality of continuous fiber material tapes are selected from the group consisting of carbon fiber tapes, glass tapes, and aramid tapes.

### EXAMPLE 35

The composite chassis of example 33, wherein the thermoplastic resin is selected from the group consisting of nylon and polymer acrylonitrile butadiene styrene.

### EXAMPLE 36

The composite chassis of example 35, wherein the thermoplastic resin is fire retardant.

### EXAMPLE 37

At least one machine-readable storage medium comprising instructions that when executed by a computing device, cause the computing device to perform the method of any of examples 1-28.

### EXAMPLE 38

An apparatus to form a composite chassis having a cosmetic finish comprising means for performing the method of any of examples 1-28.

What is claimed is:

1. A method of manufacturing a composite chassis having a cosmetic surface, the method comprising:
heating a preform, the preform comprising a plurality of composite layers impregnated with thermoplastic resin;
placing the preform in a mold;
pressurizing the mold;
injecting a first material into the mold to form one or more backside features on a first side of the preform; and
injecting a second material into the mold to form a cosmetic surface on a second side of the preform.

2. The method of claim 1, wherein the first side is different than the second side.

3. The method of claim 1, wherein the first material is different than the second material.

4. The method of claim 1, injecting the second material into the mold comprises:
opening the mold to form a cavity between the second side of the preform and an internal side of the mold; and
filling the cavity with the second material.

5. The method of claim 4, wherein the second material is a thermal set material, injecting the second material into the mold further comprises heating second material.

6. The method of claim 5, wherein the second material is selected from the group consisting of polycarbonate acrylonitrile butadiene styrene and thermoplastic-polyurethane.

7. The method of claim 1, injecting the first material into the mold comprises:
opening the mold to expose the first side of the preform;
placing a backside feature mold over the first side of the preform, the backside feature mold including one or more cavities corresponding to the one or more backside features; and
filling the one or more cavities with the first material.

8. The method of claim 1, further comprising:
laying a plurality of continuous fiber material tapes to form a composite blank; and
impregnating the composite blank with a thermoplastic resin to form the preform.

9. The method of claim 8, further comprising cutting the preform to a specified shape.

10. The method of claim 8, wherein the plurality of continuous fiber material tapes are selected from the group consisting of carbon fiber tapes, glass tapes, and aramid tapes.

11. The method of claim 8, wherein the thermoplastic resin is selected from the group consisting of nylon and polymer acrylonitrile butadiene styrene.

12. The method of claim 8, wherein the thermoplastic resin is fire retardant.

13. A method of manufacturing a composite chassis having a cosmetic surface, the method comprising:
cutting a preform comprising a plurality of composite layers impregnated with thermoplastic resin into a specified shape;
placing the preform in a mold;
placing a cosmetic film into the mold;
heating the preform and cosmetic film; and
pressurizing the mold to form the composite chassis having a cosmetic finish.

14. The method of claim 13, wherein cutting the preform includes cutting the preform to a shape corresponding to the composite chassis.

15. The method of claim 13, wherein heating the preform and cosmetic film and pressurizing the mold is done concurrently.

16. The method of claim 13, wherein heating the preform and cosmetic film and pressurizing the mold is done for less than 120 seconds.

17. The method of claim 13, wherein the cosmetic film is a thermal set material.

18. The method of claim 13, further comprising removing the composite chassis from the mold, wherein the composite chassis is netshape.

19. The method of claim 13, further comprising:
opening the mold to expose the first side of the preform;
placing a backside feature mold over the first side of the preform, the backside feature mold including one or more cavities corresponding to the one or more backside features; and
filling the one or more cavities with the first material.

20. The method of claim 13, further comprising:
laying a plurality of continuous fiber material tapes to form a composite blank; and
impregnating the composite blank with a thermoplastic resin to form the preform.

21. A composite chassis having a cosmetic finish comprising:
a first portion formed from a preform comprising a plurality of composite layers impregnated with thermoplastic resin;
a backside feature portion molded to the preform to form one or more backside features on a first side of the preform; and
a cosmetic portion molded to the preform to form a cosmetic surface on a second side of the preform.

22. The composite chassis of claim 21, wherein the cosmetic portion is selected from the group consisting of polycarbonate acrylonitrile butadiene styrene and thermoplastic-polyurethane.

23. The cosmetic chassis of claim 21, wherein the preform is a plurality of continuous fiber material tapes impregnated with a thermoplastic resin.

24. The cosmetic chassis of claim 23, wherein the plurality of continuous fiber material tapes are selected from the group consisting of carbon fiber tapes, glass tapes, and aramid tapes.

25. The composite chassis of claim 23, wherein the thermoplastic resin is selected from the group consisting of nylon and polymer acrylonitrile butadiene styrene.
